(19) United States
(12) Patent Application Publication
(10) Pub. No.: US 2004/0126908 A1
(43) Pub. Date: Jul. 1, 2004

(54) [ACTIVE MATRIX ORGANIC LIGHT EMITTING DIODE DISPLAY AND FABRICATING METHOD THEREOF]

(76) Inventor: Chih-Feng Sung, Miaoli (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/707,111

(22) Filed: Nov. 21, 2003

(30) Foreign Application Priority Data
Dec. 27, 2002 (TW) 91137634

(51) Int. Cl. H01L 21/00

(52) U.S. Cl. 438/12; 438/30

(57) ABSTRACT

A method of fabricating an active matrix organic light emitting diode display is described. A substrate having an emitting region and a non-emitting region thereon is provided. Pixel structures are formed on the substrate in the emitting region, and a power line electrically connected with the pixel structures is formed on the substrate in the non-emitting region at the same time. Then, a cap is deposited above the substrate and bonded with the substrate. The cap covers the emitting region of the substrate and the power line. Since the power line is designed inside the cap, the cap can protect the power line from damage of the outside environment thus improving the lifetime of the display.

### CROSS REFERENCE TO RELATED APPLICATIONS

This application claims the priority benefit of Taiwan application serial no. 91137634, filed Dec. 27, 2003.

### BACKGROUND OF INVENTION

1. Field of Invention

The present invention generally relates to a panel display and a fabricating method thereof, and more particularly, to an active matrix organic light emitting diode (abbreviated as AMOLED hereinafter) display and the fabricating method thereof.

2. Description of Related Art

An organic light emitting diode (OLED) is a semiconductor device that converts electric energy to photo energy with high conversion efficiency, being widely used in indication lighting, display panel, etc. Since OLED is characterized by no view angle, easy to manufacture, low cost, fast response time, wide temperature range and full color, it meets the requirements of the multimedia age display property and has become a very popular study topic in recent years.

An active matrix organic light emitting diode (AMOLED) has been aggressively developed. An organic emitting layer and a cathode layer are formed on a substrate that forms the thin film transistor (TFT) array so as to constitute an AMOLED. Therefore, a TFT is used by an AMOLED to drive a LED. The conventional method of fabricating the AMOLED is described in detail hereinafter.

FIG. 1 schematically shows a sectional view of a conventional AMOLED display.

Referring to FIG. 1, the conventional method of fabricating the AMOLED display first provides a substrate 100, wherein the substrate 100 comprises an emitting region 120 and a non-emitting region 122. Moreover, a plurality of pixel structures 107 arranged in array is formed on the substrate 100 in the emitting region 120, and each of the pixel structures 107 comprises an active matrix device (TFT) and an anode layer 102, an emitting layer 104, and a cathode layer 106.

A power line 110 electrically connected with the pixel structures 107 is formed on the substrate 100 in the non-emitting region 120 at the same time the active matrix device (TFT) is formed. Moreover, the current of each of the pixel structures 107 will eventually gather to the power line 110.

Then, a cap 114 is deposited above the substrate 100 and bonded with the substrate 100 using the frame glue (not shown). The cap 114 covers the emitting region 120 of the substrate 100 so as to protect the devices inside the emitting region 120 from any impact of the outside environment.

However, since the power line 110 is produced by the TFT manufacturing process, it is very thin (less than 1 μm) and weak. Therefore, the power line 110 is easily broken or deteriorated due to impact of the outside environment, and thus further deteriorates the whole lifetime of the AMOLED.

### SUMMARY OF INVENTION

It is thus the objective of the present invention to provide an AMOLED display and the fabricating method thereof, so as to improve the disadvantage of the conventional AMOLED's power line being easily broken or deteriorated due to the impact of outside environment.

A method of fabricating an AMOLED display is provided by the present invention. A substrate having an emitting region and a non-emitting region thereon is provided. Pixel structures are formed on the substrate in the emitting region, and a power line electrically connected with the pixel structures is formed on the substrate in the non-emitting region at the same time, wherein, each formed pixel structure comprises an active matrix device and an anode layer, an emitting layer, and a cathode layer. Moreover, the active matrix device is composed of at least two TFTs, and the power line is made of a metal material. Then, a cap is deposited above the substrate and bonded with the substrate using frame glue between the cap and the substrate, wherein the cap covers the emitting region of the substrate and the power line, so as to protect the devices inside the emitting region and the power line from damage of the outside environment.

The present invention further provides an AMOLED display that comprises a substrate, a power line, and a cap, wherein, the substrate comprises an emitting region and a non-emitting region, and a plurality of pixel structures is deposited on the substrate in the emitting region. Each of the pixel structures comprises an active matrix device and an anode layer, an emitting layer, and a cathode layer. The active matrix device is composed of at least two TFTs. Moreover, the power line is deposited on the substrate in the non-emitting region, and the power line is electrically connected with the pixel structures. Furthermore, the cap is deposited above the emitting region and bonded with the substrate using frame glue between the cap and the substrate, wherein, the cap covers the emitting region of the substrate and the power line, so as to protect the devices inside the emitting region and the power line from damage of the outside environment.

According to the present invention, the power line is deposited inside the cap, thus it can efficiently protect the power line from being broken or deteriorating due to impact of the outside environment for improving a lifetime of the display.

### BRIEF DESCRIPTION OF DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 schematically shows a sectional view of a conventional AMOLED display.

FIG. 2 schematically shows a sectional view of an AMOLED display of a preferred embodiment according to the present invention.

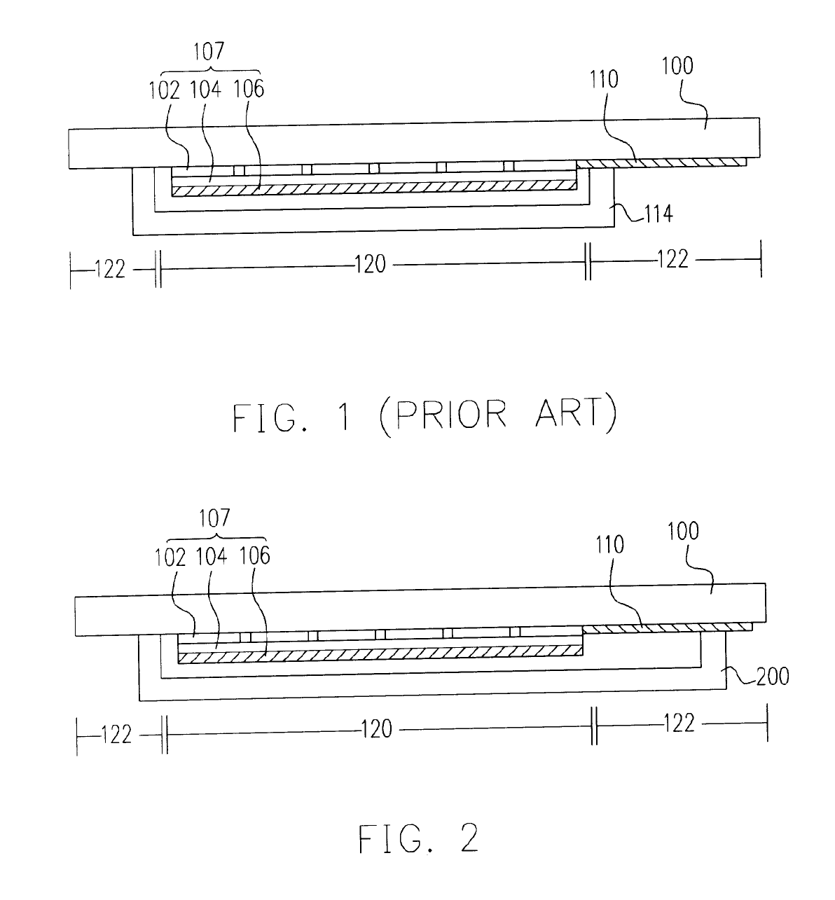

### DETAILED DESCRIPTION

Referring to FIG. 2, in the method of fabricating the AMOLED display of the present invention, a substrate 100 is provided, wherein the substrate 100 comprises an emitting region 120 and a non-emitting region 122.

Then, a plurality of pixel structures 107 arranged in array is formed on the substrate 100 in the emitting region 120, and a power line 110 is formed on the substrate 100 in the non-emitting region 120 at the same time. The power line 110 is electrically connected with the pixel structures 107. The current of each of the pixel structures 107 will eventually sink into the power line 110, so that the power provided by an external power supply (not shown) is supplied to each of the pixel structures 107. Furthermore, each of the pixel structures 107 comprises an active matrix device and an anode layer 102, an emitting layer 104, and a cathode layer 106.

For example, the active matrix device inside the pixel structure 107 is composed of at lest two TFTs. In the present embodiment, the active matrix device is composed of two TFTs, wherein one TFT is for the switching operation, the other TFT is for the driving operation.

Further, each of the pixel structures 107 is controlled by a scan line (not shown) and a data line (not shown). The scan line and the data line are defined at the same time when the gate and the source/drain of the TFT are formed, so that the power line 110 is defined at the same time when the scan line or the data line is formed. Therefore, the power line 110 of the present invention is manufactured using the TFT manufacturing process; it is very thin, just less than 1 μm. The power line 110 may be made of the same metal material as the scan line or the data line or of any other appropriate conductive material.

After the pixel structure 107 and the power line 110 are formed, a cap 200 is deposited above the substrate 100 and bonded with the substrate 100 using the frame glue (not shown) that is formed between the cap 200 and the substrate 100. The cap 200 covers the emitting region 120 of the substrate 100 and the power line 110. Specifically, the cap 200 covers the emitting region 120 of the substrate 100 and a majority of the power line 110, only a small section of the end of the power line 110 being exposed. The exposed portion of the power line 110 is electrically connected with an external power supply. In the present embodiment, the cap 200 is a metal cap or a glass cap.

Therefore, the AMOLED display of the present invention comprises a substrate 100, a power line 110, and a cap 200.

The substrate 100 comprises an emitting region 120 and a non-emitting region 122. Moreover, a plurality of pixel structures 107 is deposited on the substrate 100 in the emitting region 120, and each of the pixel structures 107 comprises an active matrix device and an anode layer 102, an emitting layer 104, and a cathode layer 106. The active matrix device is composed of at least two TFTs.

Further, the power line 110 is deposited on the substrate 100 in the non-emitting region 122. The power line 110 is electrically connected with the pixel structures 107 so that the power provided by an external power supply (not shown) is supplied to each of the pixel structures 107. In the present embodiment, the power line 110 is made of a metal material or any other appropriate conductive material.

Furthermore, the cap 200 is deposited above the substrate 100 and bonded with the substrate 100 using a frame glue that is deposited between the cap 200 and the substrate 100, wherein, the cap 200 covers the emitting region 120 of the substrate 100 and the power line 110. Specifically, the cap 200 covers the emitting region 120 of the substrate 100 and a majority of the power line 110, only a small section of the end of the power line 110 being exposed. The exposed portion of the power line 110 is electrically connected with an external power supply. In the present embodiment, the cap 200 is a metal cap or a glass cap.

Since the emitting region 120 of the substrate 100 and the majority of the power line 110 are deposited inside the cap 200, the cap 200 can protect the devices insides the emitting region 120 and the power line 110 from damage of the outside environment.

Since the power line is manufactured using the TFT manufacturing process, it is very thin and weak. If the power line is not appropriately protected, the power line is easily broken or deteriorated due to the impact of the outside environment. Therefore, according to the present invention, the power line of the AMOLED display is positioned inside the cap, so that it can effectively protect the power line from being broken or deteriorated due to impact of the outside environment for improving the whole lifetime of the display.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

1. A method of fabricating an active matrix organic light emitting diode (AMOLED) display, comprising:
providing a substrate, wherein the substrate comprises an emitting region and a non-emitting region;
forming a plurality of pixel structures on the substrate in the emitting region, and forming a power line on the substrate in the non-emitting region at the same time, wherein the power line is electrically connected with the pixel structures; and
depositing a cap above the substrate, and bonding the cap with the substrate, wherein the cap covers the emitting region of the substrate and the power line.

2. The method of fabricating the AMOLED display of claim 1, wherein the cap covers most of the power line, and only a small section of the end of the power line is exposed.

3. The method of fabricating the AMOLED display of claim 1, wherein the cap is a metal cap or a glass cap.

4. The method of fabricating the AMOLED display of claim 1, wherein each of the pixel structures is composed of an active matrix device, an anode layer, an emitting layer, and a cathode layer.

5. The method of fabricating the AMOLED display of claim 1, wherein the power line is made of a metal material.

6. An active matrix organic light emitting diode (AMOLED) display, comprising:
a substrate, wherein the substrate comprises an emitting region and a non-emitting region, and a plurality of pixel structures is deposited on the substrate in the emitting region;
a power line, wherein the power line is deposited on the substrate in the non-emitting region, and is electrically connected with the pixel structures; and
a cap, deposited above the substrate and bonded with the substrate, wherein the cap covers the emitting region of the substrate and the power line.

7. The AMOLED display of claim 6, wherein the cap covers most of the power line, and only a small section of the end of the power line is exposed.

8. The AMOLED display of claim 6, wherein the cap is a metal cap or a glass cap.

9. The AMOLED display of claim 6, wherein each of the pixel structures is composed of an active matrix device, an anode layer, an emitting layer, and a cathode layer.

10. The AMOLED display of claim 6, wherein the power line is made of a metal material.
